(19) United States
(12) Patent Application Publication
(10) Pub. No.: US 2025/0226228 A1
(43) Pub. Date: Jul. 10, 2025

(54) SUBSTRATE PROCESSING METHOD AND SUBSTRATE PROCESSING SYSTEM

(71) Applicant: Tokyo Electron Limited, Tokyo (JP)

(72) Inventors: Mitsuaki IWASHITA, Nirasaki City (JP); Yuki KIKUCHI, Nirasaki City (JP); Genji NAKAMURA, Nirasaki City (JP); Hiroyuki NAGAI, Nirasaki City (JP); Yumiko KAWANO, Nirasaki City (JP); Shuji AZUMO, Nirasaki City (JP); Keiichi FUJITA, Kikuchi-gun (JP)

(21) Appl. No.: 19/092,114

(22) Filed: Mar. 27, 2025

Related U.S. Application Data
(63) Continuation of application No. PCT/JP2023/033864, filed on Sep. 19, 2023.

(30) Foreign Application Priority Data
Sep. 30, 2022 (JP) 2022-157439

(51) Int. Cl. H01L 21/285; H01L 21/288; H01L 21/3213; H01L 21/324; H01L 21/67

(52) U.S. Cl. CPC H01L 21/28568; H01L 21/288; H01L 21/32136; H01L 21/324; H01L 21/67103; H01L 21/6723

(57) ABSTRACT

A substrate processing method includes forming a Ru film on a substrate by a non-electrolytic plating, performing a treatment using plasma of an inert gas on the substrate on which the Ru film is formed, and performing a reduction treatment on the substrate after the treatment using the plasma of the inert gas.

### CROSS-REFERENCE TO RELATED APPLICATIONS

This application is a bypass continuation application of international application No. PCT/JP2023/033864 having an international filing date of Sep. 19, 2023 and designating the United States, the international application being based upon and claiming the benefit of priority from Japanese Patent Application No. 2022-157439, filed on Sep. 30, 2022, the entire contents of which are incorporated herein by reference.

### TECHNICAL FIELD

The present disclosure relates to a substrate processing method and a substrate processing system.

### BACKGROUND

Patent Document 1 discloses that a film containing Cu, Co, Ni or Ru is formed in a via by a non-electrolytic plating using, as a catalyst, a wiring exposed from a bottom of the via formed in an insulating film provided on the wiring, thereby forming an embedded multilayer wiring.

### PRIOR ART DOCUMENT

### Patent Document

Patent Document 1: International Publication No. WO 2019/151078

### SUMMARY

According to an embodiment of the present disclosure, a substrate processing method includes forming a Ru film on a substrate by a non-electrolytic plating, performing a treatment using plasma of an inert gas on the substrate on which the Ru film is formed, and performing a reduction treatment on the substrate after the treatment using the plasma of the inert gas.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view illustrating a state in which cracks occur when forming a Ru film by a non-electrolytic plating and then performing a reduction annealing.

FIG. 2 is a flowchart for explaining a substrate processing method according to an embodiment.

FIG. 3 is a cross-sectional view illustrating a structural example of a substrate used in the substrate processing method according to the embodiment.

FIG. 4 is a cross-sectional view illustrating a state in which a Ru film is embedded in a via formed in the substrate of FIG. 3.

FIG. 5 is a block diagram illustrating a substrate processing system for carrying out the substrate processing method according to the embodiment.

FIG. 6 is a cross-sectional view illustrating an example of a non-electrolytic plating apparatus included in the substrate processing system of FIG. 5.

FIG. 7 is a cross-sectional view illustrating an example of an inert-gas plasma treatment apparatus included in the substrate processing system of FIG. 5.

FIG. 8 is a cross-sectional view illustrating an example of a reduction treatment apparatus included in the substrate processing system of FIG. 5.

### DETAILED DESCRIPTION

Embodiments of the present disclosure will now be described in detail with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### History

First, a history will be described.

Patent Document 1 discloses forming a film containing Cu, Co, Ni or Ru in a via by a non-electrolytic plating. Among these, Ru has been attracting attention as a next-generation wiring material. However, Ru is easily oxidized so that oxidation appears on a surface of a film made of Ru and in the film in an as-depo state. Further, Ru does not undergo sufficient crystallization in the as-depo state so that Ru may have a very small grain size and may be in a state close to amorphous. For this reason, the Ru film in the as-depo state has a high resistance.

In view of this point, it is conceivable to form a Ru film by a non-electrolytic plating and subsequently performing a reduction treatment such as a reduction annealing on the Ru film, thereby decomposing an oxide of Ru and promoting crystallization.

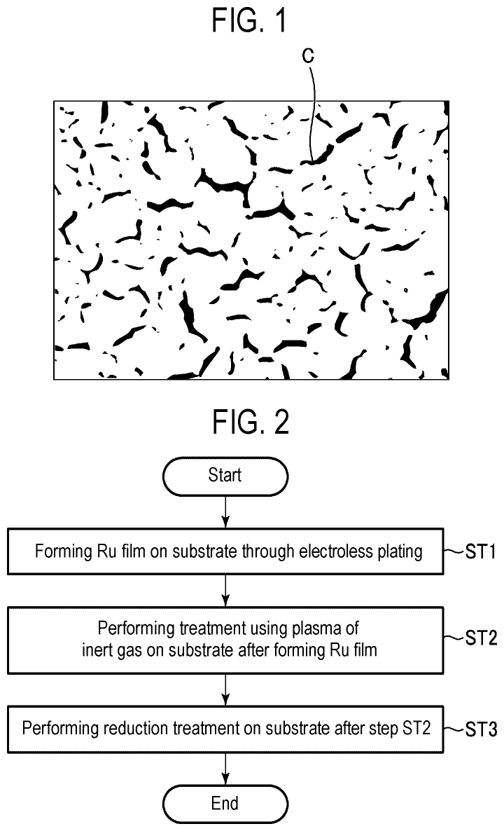

However, when the reduction treatment such as the reduction annealing is performed on the Ru film in the as-depo state, which is formed by the non-electrolytic plating, as illustrated in the schematic view of FIG. 1, it was found that cracks C occur along grain boundaries of the Ru film. A major reason why the cracks occur may be considered to be that Ru is easily oxidized and hence an oxide is formed between grains of Ru, adhesion between grains of Ru is degraded by desorption of oxygen during the reduction treatment, and volume shrinkage occurs by promotion of crystallization due to the reduction treatment.

Therefore, in an embodiment, as a post treatment performed after forming the Ru film by the non-electrolytic plating, a treatment is performed on a substrate using plasma of an inert gas such as an Ar gas or a N₂ gas, and then a reduction treatment is performed. When the treatment using the plasma of the inert gas is performed on the substrate, grains of Ru are destroyed by a physical action of the plasma of the inert gas and the oxide of Ru may be decomposed. Accordingly, the adhesion between the grains is not degraded, the cracks are suppressed from occurring due to the volume shrinkage when the crystallization is promoted by the subsequent reduction treatment, which makes it possible to stably form a low-resistance Ru film.

### Substrate Processing Method

Next, a substrate processing method according to an embodiment will be described.

FIG. 2 is a flowchart for explaining the substrate processing method according to an embodiment.

The substrate processing method of this embodiment includes an operation of forming a Ru film on a substrate by a non-electrolytic plating (Step ST1), an operation of performing a treatment on the substrate with the Ru film formed thereon using plasma of an inert gas (Step ST2), and an operation of performing a reduction treatment on the substrate after Step ST2.

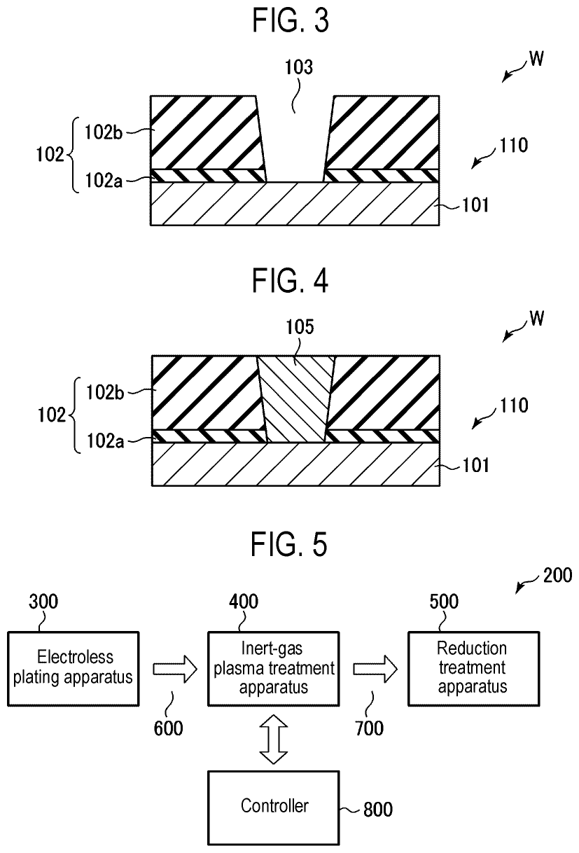

In Step ST1, the substrate is not particularly limited but may be a semiconductor substrate (semiconductor wafer) having a semiconductor base substance such as silicon (Si). For example, the substrate may be a substrate W having a structure illustrated in FIG. 3. The substrate W illustrated in FIG. 3 has a structure 110 provided on a Si base substance (not illustrated) which is the semiconductor base substance. The structure 110 includes an underlying wiring 101 and an insulating film 102 formed on the underlying wiring 101. A fine via 103 is formed in the insulating film 102. The underlying wiring 101 is exposed from a bottom of the via 103. The insulating film 102 includes a lower nitride film 102a and an upper oxide film 102b. Cu or Ru may be preferably used as a material of the underlying wiring 101. Further, Ni or Co may be used as the material of the underlying wiring 101.

The non-electrolytic plating in Step ST1 is performed by applying a chemical liquid (plating liquid) for the non-electrolytic plating onto the substrate and then heating the chemical liquid. A heating temperature at this time may be 50 degrees C. to 85 degrees C. After the heating, a drying treatment is performed on the substrate.

In the case in which the substrate has the structure illustrated in FIG. 3, as illustrated in FIG. 4, a Ru film 105 is embedded in the via 103 by performing the non-electrolytic plating. At this time, the Ru film 105 grows from the bottom of the via 103 in a bottom-up manner using, as a catalyst, the underlying wiring 101 exposed from the bottom of the via 103.

In the operation of performing the treatment using the plasma of the inert gas in Step ST2, the substrate on which the Ru film 105 is formed by the non-electrolytic plating is exposed to the plasma of the inert gas, and a physical action of the plasma acts on the Ru film. As a result, Ru grains of the oxidized Ru film are destroyed so that a Ru oxide formed by the oxidization of the Ru film may be decomposed.

The plasma-based treatment in Step ST2 is performed in a vacuum atmosphere. A pressure at that time may be within a range of 100 mTorr to 2 Torr (13.3 Pa to 266.6 Pa). In addition, a temperature of the substrate may be within a range of 70 degrees C. to 400 degrees C., specifically a range of 70 degrees C. to 130 degrees C., more specifically a range of 100 degrees C. to 130 degrees C. When the temperature exceeds 130 degrees C., degassing tends to increase. A time period required for the treatment in Step ST2 may be 5 seconds to 300 seconds. A noble gas such as an Ar gas or a He gas, a N₂ gas, or the like may be used as the inert gas. Among these, the Ar gas or the N₂ gas may be preferably used. In particular, the Ar gas which has a large atomicity and a large physical action may be preferably used. The Ar gas may be used 100%, but two or more inert gases, such as Ar gas+He gas, and Ar gas+N₂ gas, may be mixed with each other and used. The plasma used in Step ST2 is not particularly limited, but various plasma, such as a capacitively coupled plasma, an inductively coupled plasma, and a microwave plasma and the like, may be used.

In addition, in Step ST2, a bias may be applied to the substrate. When the bias is applied to the substrate, ions in the plasma may be drawn into the substrate. This increases the physical action acting on the Ru film on the surface of the substrate. In particular, Ar ions having a large atomicity may be drawn into the substrate to obtain a significant effect. The bias may be a radio frequency bias.

The operation of performing the reduction treatment on the substrate in Step ST3 is an operation of promoting the crystallization of the Ru film while reducing a portion of the Ru film, which has been oxidized, thereby reducing a resistance of the Ru film.

The reduction treatment may be a reduction annealing or a hydrogen-plasma treatment. The reduction annealing is a treatment of heating the substrate while supplying a reducing gas, and may be an atmospheric-pressure treatment. The hydrogen-plasma treatment is a treatment of treating the substrate using plasma of a gas including a H₂ gas, for example, the H₂ gas alone, or a mixed gas of the H₂ gas and the inert gas, and may be a vacuum treatment.

In the case in which the reduction treatment is the reduction annealing, the substrate temperature may be 200 degrees C. to 430 degrees C., for example, 400 degrees C. Examples of the reducing gas may be a foaming gas, a H₂ gas, a formic acid, and the like. At least one of these gases may be preferably used. The foaming gas is a mixed gas of the H₂ gas and the N₂ gas. The H₂ gas may have an explosion limit of 5.7% or less, for example, 4%. A time period required for the reduction annealing may vary according to a thickness of the Ru film, but may be about 5 to 120 minutes. Even if the reduction annealing is the atmospheric-pressure treatment, it may be performed using an apparatus having a hermetically-sealed structure to maintain a gas composition.

In the case in which the reduction treatment is the hydrogen-plasma treatment, the treatment may be performed in the vacuum atmosphere as described above. A pressure at that time may be within a range of 100 mTorr to 2 Torr (13.3 Pa to 266.6 Pa). In addition, the substrate temperature may be within a range of 70 degrees C. to 400 degrees C., specifically a range of 70 degrees C. to 130 degrees C., more specifically a range of 100 degrees C. to 130 degrees C. The hydrogen-plasma treatment may be performed using plasma of the H₂ gas, or plasma of the H₂ gas and the inert gas. The plasma at this time is not particularly limited but various plasma, such as a capacitively-coupled plasma, an inductively-coupled plasma, and a microwave plasma, may be used. When the reduction treatment is the hydrogen-plasma treatment, it may be performed using the apparatus which performs the treatment using the plasma of the inert gas in Step ST2.

As described above, in this embodiment, by performing the reduction treatment in Step ST3 after the treatment using the plasma of the inert gas in Step ST2, it is possible to suppress the adhesion between the grains from being reduced due to the oxygen desorption and suppress the cracks from occurring due to the promotion of crystallization during the reduction treatment.

That is, in the treatment using the plasma of the inert gas in Step ST2, the Ru grains may be destroyed and the Ru oxide may be decomposed. This makes it possible to suppress the adhesion between the grains from being reduced, and suppress the cracks from occurring due to the volume shrinkage during the subsequent reduction treatment.

As a reaction model used in the plasma treatment in Step ST2, it is presumed that the plasma treatment is similar to destruction of Si crystals, which occurs when a substrate is doped with impurities by implantation, and amorphousness.

As described above, according to this embodiment, the Ru film formed by the non-electrolytic plating may be reduced without causing the cracks, which makes it possible to stably form a low-resistance Ru film.

Further, a substrate having the structure in which the fine via 103 illustrated in FIG. 3 is formed is used as the substrate. In the case in which the Ru film is embedded in the via 103, it is difficult to implement a void-less embedding by CVD or PVD in the related art. However, according to this embodiment, by using the non-electrolytic plating, it is possible to implement the void-less embedding. That is, in the non-electrolytic plating, Ru selectively grows from the underlying wiring 101 using, as a catalyst, the underlying wiring 101 exposed from the bottom of the via 103, and is embedded in the via 103 in a bottom-up manner. Thus, even if the via is fine, it may be filled with Ru without void. In addition, a temperature in film formation is low in the order of less than 100 degrees C. Further, in this embodiment, as described above, the low-resistance Ru film may be obtained by the non-electrolytic plating without causing the cracks, which makes it possible to provide advantages when Ru is embedded in the via by the non-electrolytic plating.

### Substrate Processing System

Next, a substrate processing system for carrying out the above substrate processing method will be described.

FIG. 5 is a block diagram illustrating the substrate processing system for carrying out the substrate processing method of the embodiment.

A substrate processing system 200 includes a non-electrolytic plating apparatus 300, an inert-gas plasma treatment apparatus 400, and a reduction treatment apparatus 500. The transfer of the substrate between the non-electrolytic plating apparatus 300 and the inert-gas plasma treatment apparatus 400 and the transfer of the substrate between the inert-gas plasma treatment apparatus 400 and the reduction treatment apparatus 500 are performed by substrate transfer mechanisms 600 and 700, respectively. Further, the substrate processing system 200 includes a controller 800 configured to control the non-electrolytic plating apparatus 300, the inert-gas plasma treatment apparatus 400, the reduction treatment apparatus 500, and the substrate transfer mechanisms 600 and 700. Hereinafter, these constituent elements will be described individually.

### Non-Electrolytic Plating Apparatus

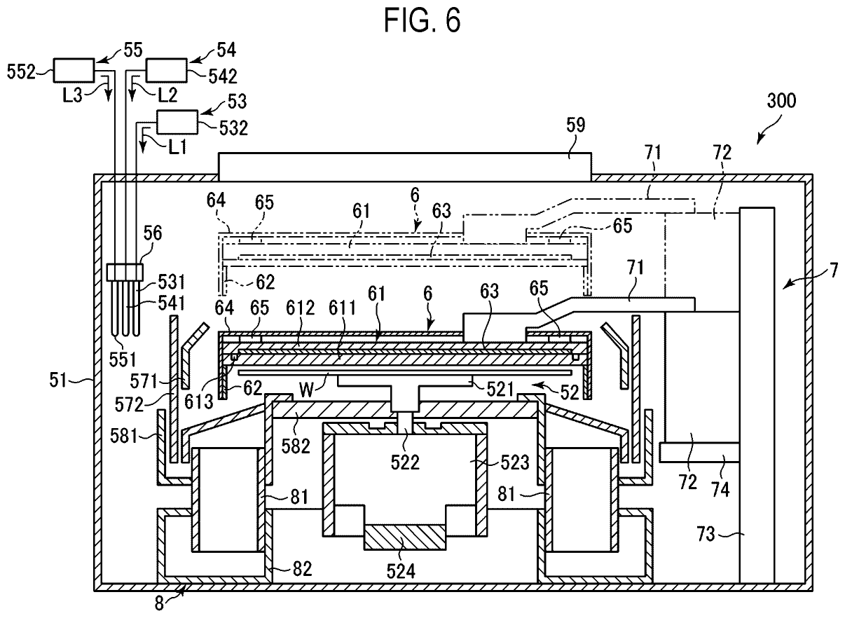

FIG. 6 is a cross-sectional view illustrating an example of the non-electrolytic plating apparatus 300. The non-electrolytic plating apparatus 300 forms the Ru film by the non-electrolytic plating, and includes a chamber 51, a substrate holder 52, and a plating liquid supply 53. The substrate holder 52 is disposed in the chamber 51 and includes a chuck member 521 configured to vacuum-suction a lower surface (rear surface) of the substrate W to horizontally holds the substrate W. The substrate holder 52 may be a mechanical chuck. The plating liquid supply 53 supplies a plating liquid L1 onto an upper surface (treatment surface) of the substrate W held by the substrate holder 52.

A rotary motor 523 is connected to the substrate holder 52 via a rotary shaft 522. When the rotary motor 523 is driven, the substrate holder 52 rotates together with the substrate W. The rotary motor 523 is supported by a base 524 fixed to the chamber 51.

The plating liquid supply 53 includes a plating liquid nozzle 531 configured to discharge the plating liquid L1 onto the substrate W held by the substrate holder 52, and a plating liquid source 532 configured to supply the plating liquid L1 to the plating liquid nozzle 531. The plating liquid source 532 supplies the plating liquid L1, of which a temperature is adjusted to a predetermined temperature, to the plating liquid nozzle 531. The plating liquid nozzle 531 is configured to be movable while being held by a nozzle arm 56.

The plating liquid L1 may be a plating liquid for autocatalytic type (reduction type) non-electrolytic plating, and contains Ru ions and reductant such hypophosphorous acid, dimethylamine borane, hydrazine or the like. The plating liquid L1 may contain a suitable additive. By discharging the plating liquid L1 from the plating liquid nozzle 531, the Ru film is applied onto the upper surface of the substrate W.

The non-electrolytic plating apparatus 300 further includes, as other treatment liquid supplies, a cleaning liquid supply 54 configured to supply a cleaning liquid L2 onto the upper surface of the substrate W held by the substrate holder 52, and a rinsing liquid supply 55 configured to supply a rinsing liquid L3 onto the upper surface of the substrate W.

The cleansing liquid supply 54 includes a cleaning liquid nozzle 541 configured to discharge the cleaning liquid L2 onto the substrate W held by the substrate holder 52, and a cleaning liquid source 542 configured to supply the cleaning liquid L2 to the cleaning liquid nozzle 541. As the cleaning liquid L2, for example, an organic acid or a diluted hydrofluoric acid (DHF) may be used. The cleaning liquid nozzle 541 may be configured to be movable together with the plating liquid nozzle 531 while being held by the nozzle arm 56.

The rinsing liquid supply 55 includes a rinsing liquid nozzle 551 configured to discharge the rinsing liquid L3 onto the substrate W held by the substrate holder 52, and a rinsing liquid source 552 configured to supply the rinsing liquid L3 to the rinsing liquid nozzle 551. The rinsing liquid nozzle 551 may be configured to be movable together with the plating liquid nozzle 531 and the cleaning liquid nozzle 541 while being held by the nozzle arm 56. As the rinsing liquid L3, for example, pure water may be used.

The nozzle arm 56 which holds the plating liquid nozzle 531, the cleaning liquid nozzle 541, and the rinsing liquid nozzle 551 is configured to move in a horizontal direction and a vertical direction by a nozzle moving mechanism which is not illustrated. The nozzle arm 56 is movable between a discharge position at which the plating liquid L1, the cleaning liquid L2, or the rinsing liquid L3 is discharged, and a retreat position which is withdrawn from the discharge position. The discharge position is a position at which a liquid may be supplied to a certain position on the upper surface of the substrate W. For example, the discharge position is a position at which the liquid may be supplied to the center of the substrate W. The retreat position is a position defined outside the substrate W.

A cup 571 is provided at the periphery of the substrate holder 52. The cup 571, which is formed in a ring shape, receives a liquid scattered from the substrate W when the substrate W is rotated and guides the same to a drain duct 581 which will be described later. An atmosphere blocking cover 527 is provided at an outer circumferential side of the cup 571 so that an atmosphere at the periphery of the substrate W is suppressed from diffusing into the chamber 51. The atmosphere blocking cover 572 is formed in a cylindrical shape to extend in the vertical direction, and has an open upper end. A cover body 6 (to be described later) is provided to be insertable into the atmosphere blocking cover 572 from above.

The drain duct 581 is provided below the cup 571. The drain duct 581, which is formed in a ring shape, receives and discharges a liquid which is received by the cup 571 and falls from the cup 571, or a treatment liquid which directly falls from the periphery of the substrate W. An inner cover 582 is provided at an inner circumferential side of the drain duct 581.

The upper surface of the substrate W held by the substrate holder 52 is covered by the cover body 6. The cover body 6 includes a ceiling portion 61 extending in the horizontal direction and a sidewall portion 62 extending downward from the ceiling portion 61. When the cover body 6 is located at a downward position (that is, a processing position) which will be described later, the ceiling portion 61 faces the substrate W held by the substrate holder 52 at a relatively small interval.

The ceiling portion 61 includes a first ceiling plate 611 and a second ceiling plate 612 provided on the first ceiling plate 611. The first ceiling plate 611 and the second ceiling plate 612 are provided to sandwich a heater 63 therebetween. A sealing ring 613 is provided at an outer circumferential side of the heater 63 between the first ceiling plate 611 and the second ceiling plate 612. The heater 63 is sealed by the sealing ring 613 and is configured so as not be in contact with a liquid such as the plating liquid L1. The first ceiling plate 611 and the second ceiling plate 612 may be made of a suitable material, for example, an aluminum alloy, which has corrosion resistance to the liquid such as the plating liquid L1. In addition, in order to enhance the corrosion resistance, the first ceiling plate 611, the second ceiling plate 612, and the sidewall portion 62 may be coated with Teflon (registered trademark).

A cover-body moving mechanism 7 is connected to the cover body 6 via a cover-body arm 71. The cover-body moving mechanism 7 includes a swing motor 72 configured to move the cover body 6 in the horizontal direction, and a cylinder 73 configured to move the cover body 6 in the vertical direction. The swing motor 72 is installed on a support plate 74 provided to be movable in the vertical direction with respect to the cylinder 73.

The swing motor 72 of the cover-body moving mechanism 7 moves the cover body 6 between an upward position defined above the substrate W held by the substrate holder 52 and the retreat position withdrawn from the upward position. The retreat position is a position defined outside the substrate W in the chamber 51. A rotational axis line of the swing motor 72 extends in the vertical direction, and the cover body 6 is provided to be rotatably movable in the horizontal direction between the upward position and the retreat position.

The cylinder 73 of the cover-body moving mechanism 7 moves the cover body 6 between the downward position (position indicated by a solid line in FIG. 6) and the upper position (position indicated by an alternate long and two short dash line in FIG. 6), and adjusts a gap between the substrate W having the plating liquid L1 applied onto the upper surface thereof and the first ceiling plate 611 of the ceiling portion 61. When the cover body 6 is located at the downward position, the first ceiling plate 611 approaches the substrate W.

When the cover body 6 is located at the downward position described above, the plating liquid L1 on the substrate W is heated by the heater 63.

The sidewall portion 62 of the cover body 6 extends downward from a peripheral portion of the first ceiling plate 611 of the ceiling portion 61. When the cover body 6 is located at the downward position where the plating liquid L1 on the substrate W is heated, the cover body 6 is located at an outer circumferential side of the substrate W.

The ceiling portion 61 and the sidewall portion 62 of the cover body 6 are covered by a cover-body cover 64. The cover-body cover 64 is placed on the second ceiling plate 612 of the cover body 6 via a plurality of supports 65. In order to suppress an internal heat of the cover body 6 from releasing to the periphery of the cover body 6, the cover-body cover 64 may be made of a material, for example, a resin material, which has a heat insulation property higher than that of the ceiling portion 61 and the sidewall portion 62.

A fan filter unit 59 configured to supply clean air to the periphery of the cover body 6 is provided at an upper portion of the chamber 51. The fan filter unit 59 supplies air into the chamber 51 (specifically, the atmosphere blocking cover 572). The supplied air flows toward an exhaust tube 81 which will be described later. A down-flow in which the air flows downward is formed at the periphery of the cover body 6. A gas evaporated from a treatment liquid such as the plating liquid L1 flows toward the exhaust tube 81 by such a down-flow. Accordingly, the gas evaporated from the treatment liquid is prevented from rising and diffusing into the chamber 51.

The gas supplied from the above-described fan filter unit 59 is discharged by an exhaust mechanism 8. The exhaust mechanism 8 includes two exhaust tubes 81 provided below the cup 571 and an exhaust duct 82 provided below the drain duct 581. Each of the two exhaust tubes 81 is in communication with the exhaust duct 82 while passing through a bottom of the drain duct 581. The exhaust duct 82 is formed in a substantially semicircular ring shape when viewed from above. One exhaust duct 82 is provided below the drain duct 581, and two exhaust tubes 81 are in communication with the exhaust duct 82.

In the non-electrolytic plating apparatus 300 configured as above, first, in a state in which the clean air is supplied into the chamber 51 from the fan filter unit 59, the substrate W is loaded into the non-electrolytic plating apparatus 300 where the substrate W is horizontally held by the substrate holder 52.

Subsequently, the cleaning treatment is performed on the substrate W held by the substrate holder 52. In the cleaning treatment, the substrate W rotates at a predetermined rotation speed by the rotary motor 523, the nozzle arm 56 is moved from the retreat position to the discharge position, and the cleaning liquid L2 from the cleaning liquid nozzle 541 is supplied onto the upper surface of the substrate W which is rotating. Accordingly, the upper surface of the substrate W is cleaned to remove deposits or the like. The cleaning liquid L2 supplied onto the substrate W is discharged to the drain duct 581.

Subsequently, the rinsing treatment is performed on the substrate W. In the rinsing treatment, the rinsing liquid L3 from the rinsing liquid nozzle 551 is supplied onto the substrate W which is rotating, to rinse the upper surface of the substrate W. Accordingly, the cleaning liquid L2 remaining on the substrate W is washed away. The rinsing liquid L3 supplied onto the substrate W is discharged to the drain duct 581.

Subsequently, the plating liquid L1 is supplied onto the upper surface of the substrate W held by the substrate holder 52 to form a paddle of the plating liquid L1 on the upper surface of the substrate W. The formation of the paddle on the upper surface of the substrate W may be performed as follows. First, in a state in which the substrate W rotates at a rotation speed smaller than that in the rinsing treatment, the plating liquid L1 is discharged from the plating liquid nozzle 531 onto the upper surface of the substrate W. The plating liquid L1 stays on the upper surface by virtue of a surface tension to form a layer of the plating liquid L1, that is, the paddle. A portion of the plating liquid L1 flows out from the upper surface and is discharged via the drain duct 581. After a predetermined amount of the plating liquid L1 is discharged from the plating liquid nozzle 531, the discharge of the plating liquid L1 is stopped. Thereafter, the nozzle arm 56 is withdrawn to the retreat position. By forming the paddle while rotating the substrate W in this way, it is possible to make a plating film uniform. Further, an amount of the plating liquid L1 gathered on the substrate may be increased by stopping the rotation of the substrate W.

Subsequently, a treatment of heating the plating liquid L1 gathered on the substrate W is performed. Such a plating-liquid heating treatment includes an operation of covering the substrate W with the cover body 6, an operation of supplying an inert gas, an operation of locating the cover body 6 at the downward position and actually heating the plating liquid L1, and an operation of withdrawing the cover body 6 from above the substrate W. In addition, even when the treatment of heating the plating liquid L1 is performed, the rotation speed of the substrate W (including the case of stopping the rotation of the substrate W) may be maintained like in the case of gathering the plating liquid.

The operation of supplying the inert gas is an operation of supplying the inert gas from an inert-gas supply mechanism (to be described later) to a space between the substrate W held by the substrate holder 52 and the cover body 6 located at the downward position, and performing a plating treatment on the upper surface of the substrate W while maintaining the periphery of the substrate W in a low oxygen atmosphere.

By the operation of actually heating the plating liquid L1, when the temperature of the plating liquid L1 is raised to a temperature at which a component in the plating liquid L1 is precipitated, the component in the plating liquid L1 is precipitated on the upper surface of the substrate W, so that the plating film (Ru film) is formed and grows. This heating operation is performed at the temperature of the plating liquid L1 at which the plating film is precipitated, for example, 50 degrees C. to 85 degrees C., for a time period required to obtain the plating film with a desired thickness.

Subsequently, the rinsing treatment is performed on the substrate W. In the rinsing process, first, the rotation speed of the substrate W is increased as compared with that in the plating treatment (the formation of the paddle and the heating treatment). For example, the substrate W is rotated at, for example, the same rotation speed as the rinsing treatment before the plating treatment. Subsequently, the rinsing liquid nozzle 551 is moved from the retreat position to the discharge position. Subsequently, the rinsing liquid L3 from the rinsing liquid nozzle 551 is supplied onto the substrate W which is rotating, to wash away the plating liquid L1 remaining on the substrate W.

Subsequently, the drying treatment is performed on the substrate W. In the drying treatment, the substrate W is rotated at a relatively high speed to shake off and dry the rinsing liquid L2 remaining on the substrate W. Accordingly, the substrate having the Ru film, which is a non-electrolytic plating film in a dried state, may be obtained. In this case, the drying may be promoted by spraying the inert gas such as a N₂ gas toward the substrate W.

After that, the substrate W is taken out of the substrate holder 52 and is unloaded from the non-electrolytic plating apparatus 300.

Further, in practice, a plurality of non-electrolytic plating apparatuses 300, which is unitized, may be disposed in a loading/unloading station. A substrate in a substrate accommodation container which accommodates a plurality of substrates may be transferred by a transfer mechanism to one of the plurality of non-electrolytic plating apparatuses 300 where the substrate is processed.

### Inert-Gas Plasma Treatment Apparatus

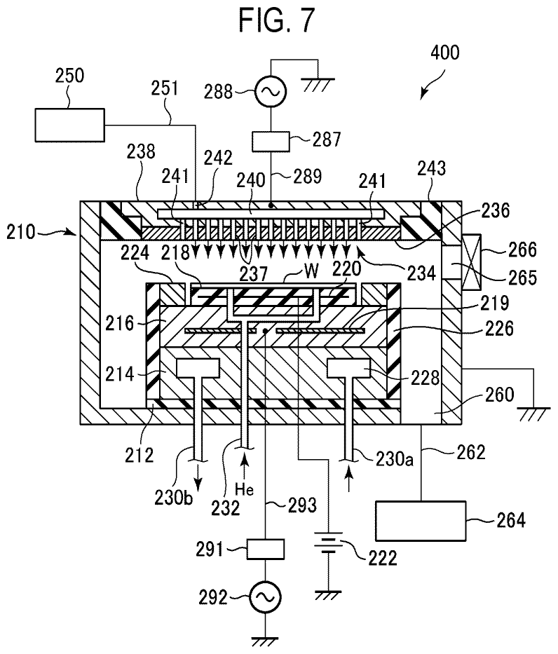

FIG. 7 is a cross-sectional view illustrating an example of the inert-gas plasma treatment apparatus 400. The inert-gas plasma treatment apparatus 400 performs an inert gas-based plasma treatment on the Ru film formed by the non-electrolytic plating, and is configured as a capacitively-coupled plasma treatment apparatus.

The inert-gas plasma treatment apparatus 400 includes a processing container (chamber) 210 which is formed in a substantially cylindrical shape and is made of a metal, for example, aluminum whose surface is anodized. The processing container 210 is securely grounded.

A cylindrical metal support 214 is disposed at the bottom of the processing container 210 via an insulating plate 212 made of a ceramic or the like. A substrate stage 216 made of a metal, for example, aluminum, is provided on the support 214. The substrate stage 216 constitutes a lower electrode. An electrostatic chuck 218 configured to attractively hold the substrate W by an electrostatic force is provided on an upper surface of the substrate stage 216. The electrostatic chuck 218 has a structure in which an electrode 220 is provided inside an insulator. When a DC voltage is applied from a suction DC power source 222 to the electrode 220, the substrate W is attractively held by the electrostatic chuck 218 by virtue of the electrostatic force such as Coulomb force.

A conductive focus ring 224 made of, for example, silicon, is disposed at a peripheral portion of the electrostatic chuck 218 to improve the uniformity of the plasma treatment. A cylindrical inner wall member 226 made of, for example, quartz, is provided on side surfaces of the substrate stage 216 and the support 214.

A temperature adjustment mechanism 228 is provided inside the support 214. A temperature adjustment medium from an external chiller unit (to be described later) is supplied in a circulation manner into the temperature adjustment mechanism 228 via pipes 230a and 230b. In addition, a heater 219 is provided inside the substrate stage 216. The temperature of the substrate W is controlled by the temperature adjustment mechanism 228 and the heater 219 to a desired temperature in a range of, for example, 70 degrees C. to 400 degrees C.

In addition, a heat transfer gas (for example, a He gas) from a heat-transfer-gas supply mechanism (to be described later) is supplied between an upper surface of the electrostatic chuck 218 and a rear surface of the substrate W via a gas supply line 232.

An upper electrode 234 is provided above the substrate stage (the lower electrode) 216 to face the substrate stage 216. In addition, a space between the upper electrode 234 and the substrate stage (the lower electrode) 216 becomes a plasma generation space.

The upper electrode 234 is supported at an upper portion of the processing container 210 with an insulative shielding member 243. The upper electrode 234 is constituted with an electrode plate 236 which constitutes a surface facing the substrate stage 216 and has a plurality of gas discharge holes 237, and an electrode support 238 which has a water-cooling structure and configured to detachably support the electrode plate 236. A gas diffusion chamber 240 is provided inside the electrode support 238. A plurality of gas flow holes 241 in communication with the gas discharge holes 237 extend downward from the gas diffusion chamber 240. A gas introduction port 242 configured to introduce an inert gas into the gas diffusion chamber 240 therethrough is formed in the electrode support 238. A gas pipe 251 connected to a gas supply 250 (to be described later) is connected to the gas introduction port 242. In addition, the inert gas supplied from the gas supply 250 is supplied into the gas diffusion chamber 240, and is supplied into the plasma generation space in the processing container 210 via the gas flow holes 241 and the gas discharge holes 237. That is, the upper electrode 234 is configured as a shower head.

The gas supply 250 supplies the inert gas for generating a plasma, and includes a gas source, a pipe, and a flow controller. The inert gas from the gas supply 250 is supplied into the gas diffusion chamber 240 via the gas pipe 251 as described above. A noble gas such as an Ar gas or a He gas, a N₂ gas, or the like may be used as the inert gas supplied from the gas supply 250. Among these, the Ar gas which has a large atomicity and a large physical action may be preferably used. Two or more inert gases may be mixed with each other.

An exhaust port 260 is provided in the bottom of the processing container 210. An exhaust device 264 is connected to the exhaust port 260 via an exhaust pipe 262. The exhaust device 264 includes an automatic pressure control valve and a vacuum pump. The exhaust device 264 is configured to exhaust an interior of the processing container 210 so that the interior of the processing container 210 is kept at a desired level of vacuum. A loading/unloading port 265 for loading/unloading the substrate W with respect to the processing container 210 therethrough is provided in the sidewall of the processing container 210. The loading/unloading port 265 is configured to be opened/closed by a gate valve 266.

A first radio-frequency power source 288, which is used for plasma generation, is electrically connected to the upper electrode 234. A first matcher 287 is provided in a feeding line 289 configured to feed electric power to the upper electrode 234 from the first radio-frequency power source 288. When radio-frequency power is supplied to the upper electrode 234 from the first radio-frequency power source 288, a radio-frequency electric field is formed in the plasma generation space between the upper electrode 234 and the substrate stage (the lower electrode) 216 to generate a capacitively-coupled plasma. The radio-frequency power supplied from the first radio-frequency power source 288 may have a frequency of 0.4 MHz to 100 MHz and a power of 100 W to 300 W. The first matcher 287 is configured to match a load (plasma) impedance to an impedance at a side of the first radio-frequency power source 288.

A second radio-frequency power source 292, which is used for bias application, is electrically connected to the substrate stage 216 which is the lower electrode. A second matcher 291 is provided in a feeding line 293 configured to feed electric power to the substrate stage 216 from the second radio-frequency power source 292. When radio-frequency power is supplied to the substrate stage 216 from the second radio-frequency power source 292, a bias is applied to the substrate W so that ions are drawn into the substrate W. By applying the bias to the substrate W to draw ions (in particular, Ar ions) in the plasma into the substrate W, it is possible to increase the physical action actin on the Ru film on the surface of the substrate W. The radio-frequency power supplied from the second radio-frequency power source 292 may have a frequency of 0.4 MHz to 100 MHz and a power of 100 W to 1,000 W. The second matcher 291 is configured to match a load (plasma) impedance to an impedance at a side of the second radio-frequency power source 292. The second radio-frequency power source 292 is not essential but may be provided from the viewpoint of increasing the physical action acting on the substrate W.

In the inert-gas plasma treatment apparatus 400 configured as described above, first, the substrate W is loaded into the processing container 210 and is placed on the substrate stage 216. A temperature of the substrate stage 216 is controlled by the temperature adjustment mechanism 228 and the heater 219 such that the temperature of the substrate W placed on the substrate stage 216 is 70 degrees C. to 400 degrees C., specifically 70 degrees C. to 130 degrees C., more specifically 100 degrees C. to 130 degrees C.

Subsequently, after the processing container 210 is vacuum-exhausted, an internal pressure of the processing container 210 is adjusted to, for example, 100 mTorr to 2 Torr (13.3 Pa to 266.6 Pa) while the inert gas is supplied into the processing container 210.

In this state, the radio-frequency power from the first radio-frequency power source 288, which is used for plasma generation, is supplied to the upper electrode 234 while the inert gas is supplied from the gas supply 250. Thus, the capacitively-coupled plasma is generated in the plasma generation space so that the physical action by the plasma acts on the Ru film on the surface of the substrate W. Further, the radio-frequency power from the second radio-frequency power source 292, which is used for bias application, is supplied to the substrate stage 216 which is the lower electrode, so that the bias is applied to the substrate W and ions in the plasma are drawn into the substrate W. Accordingly, the physical action acting on the Ru film is increased. In particular, when the Ar gas having a large atomicity is used as the inert gas, the physical action acting on the Ru film may be further increased.

After the plasma treatment described above is performed for a predetermined period of time, for example, 5 seconds to 300 seconds, the plasma comes into an off-state, the interior of the processing container 210 is purged with the inert gas, and subsequently, the substrate W is unloaded from the processing container 210.

In addition, in this example, while an example in which the capacitively-coupled plasma is used is illustrated, another plasma such as an inductively-coupled plasma or a microwave plasma may be used.

In addition, in practice, the inter-gas plasma treatment apparatus 400 is incorporated in a system which is connected to the vacuum transfer chamber kept in a vacuum and is configured such that the substrate is transferred to the inter-gas plasma treatment apparatus 400 from the substrate accommodation container disposed in the loading/unloading station via a load lock chamber by a transfer mechanism included in the vacuum transfer chamber

### Reduction Treatment Apparatus

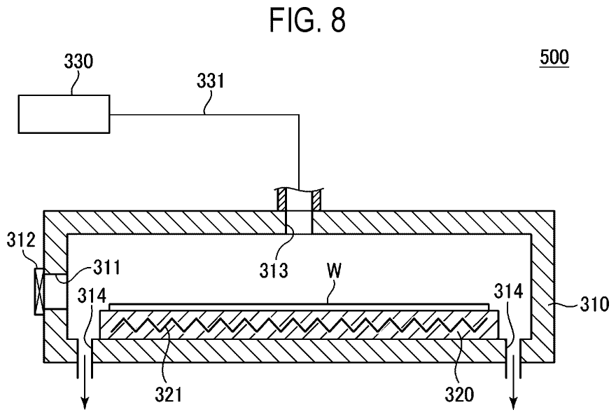

FIG. 8 is a cross-sectional view illustrating an example of the reduction treatment apparatus 500. The reduction treatment apparatus 500 includes a processing container 310, a heating plate 320, and a gas supply 330.

The processing container 310 is a metal-made container formed in a substantially cylindrical shape with a substantially hermetically-sealed structure. An interior of the processing container 310 is maintained at an atmospheric pressure. The heating plate 320 is provided at the center of a bottom portion of the interior of the processing container 310. A loading/unloading port 311 configured to load/unload the substrate W therethrough is formed in a sidewall of the processing container 310. The loading/unloading port 311 is opened/closed by a shutter 312. In addition, a gas introduction port 313 configured to introduce a reducing gas therethrough is formed at the center of a ceiling wall of the processing container 310. A plurality of exhaust ports 314 is formed outside the heating plate 320 in a bottom wall of the processing container 310.

The heating plate 320 is made of a metal, and heats the substrate W placed thereon. A heater 321 is embedded in the heating plate 320. The heater 321 heats the heating plate 320 such that a temperature of the substrate W placed on the heating plate 320 is 200 degrees C. to 430 degrees C., for example, 400 degrees C.

The gas supply 330 supplies the reducing gas into the processing container 310 via a pipe 331 and the gas introduction port 313. A foaming gas, a H₂ gas, a formic acid, or the like may be used as the reducing gas.

In the reduction treatment apparatus 500 configured as described above, first, the substrate W which has been subjected to the plasma treatment with the inert gas, is loaded into the processing container 310 by a transfer mechanism (not illustrated), and is placed on the heating plate 320. At this time, a temperature of the heating plate 320 is controlled by the heater 321 such that the temperature of the substrate W placed on the heating plate 320 is 200 degrees C. to 430 degrees C., for example, 400 degrees C.

Subsequently, the reduction treatment is performed on the substrate W placed on the heating plate 320 by supplying the reducing gas into the processing container 310 from the gas supply 330. As a result, an oxidized portion of the Ru film is reduced, and the crystallization of the Ru film is promoted to reduce the resistance of the Ru film. A treatment time at this time may be about 5 minutes to 120 minutes.

After the reducing gas is supplied for a predetermined period of time, the supply of the reducing gas is stopped, and the substrate W placed on the heating plate 320 is unloaded from the processing container 310 by the transfer mechanism (not illustrated).

In addition, in practice, the reduction treatment apparatus 500 configured as a reduction annealing apparatus is incorporated in a system configured such that the substrate is transferred to the reduction treatment apparatus 500 from the substrate accommodation container disposed in the loading/unloading station by the transfer mechanism.

In addition, in the above example, the reduction treatment apparatus 500 has been described to perform the reduction annealing at the atmospheric pressure. Alternatively, a hydrogen-plasma treatment apparatus configured to perform a hydrogen-plasma treatment may be used as the reduction treatment apparatus 500. As the hydrogen-plasma treatment apparatus, an apparatus which has a structure similar to that of the inert-gas plasma treatment apparatus 400 illustrated in FIG. 7, and uses a H₂ gas or a mixed gas of the H₂ gas and an inert gas as a gas supplied from a gas supply, may be used. However, in the hydrogen-plasma treatment apparatus, a radio-frequency power source for bias may be omitted. In addition, the gas supply 250 of the inert-gas plasma treatment apparatus 400 illustrated in FIG. 7 may have a function of supplying the H₂ gas to perform the reduction treatment in the inert-gas plasma treatment apparatus 400.

In the case in which the reduction annealing apparatus is used as the reduction treatment apparatus 500, the inert-gas plasma treatment apparatus 400 in which the vacuum treatment is performed needs to be kept at the atmospheric pressure. Meanwhile, in the case of the hydrogen-plasma treatment, the reduction treatment corresponds to the vacuum treatment. Thus, the inert-gas plasma treatment and the hydrogen-plasma treatment may be implemented using a single vacuum system, which is efficient. Further, by configuring the inert-gas plasma treatment apparatus 400 to perform the hydrogen-plasma treatment (by configuring the inert-gas plasma treatment apparatus 400 and the reduction treatment apparatus 500 as a single treatment apparatus), it is possible to implement a highly efficient substrate processing system.

### Substrate Transfer Mechanisms

Each of the substrate transfer mechanisms 600 and 700 transfers the substrate between the non-electrolytic plating apparatus 300 and the inert-gas plasma treatment apparatus 400, and between the inert-gas plasma treatment apparatus 400 and the reduction treatment apparatus 500 in the state in which the plurality of substrates is accommodated in the substrate accommodation container. In order to suppress the oxidation of the Ru film formed by the non-electrolytic plating, each of the substrate transfer mechanisms 600 and 700 may transfer the substrate in a state in which the substrate accommodation container is maintained in a non-oxidizing atmosphere such as an inert atmosphere or a reductive atmosphere.

### Controller

The controller 800 controls individual constituent elements of the substrate processing system 200, that is, the non-electrolytic plating apparatus 300, the inert-gas plasma treatment apparatus 400, the reduction treatment apparatus 500, and the substrate transfer mechanisms 600 and 700. The controller 800 includes a main controller equipped with a CPU (computer), an input device, an output device, a display device, and a storage device. The main controller of the controller 800 causes the substrate processing system 200 to execute a desired operation based on a processing recipe stored in a recording medium built in the storage device or a recording medium set in the storage device.

In the substrate processing system 200, the non-electrolytic plating apparatus 300, the inert-gas plasma treatment apparatus 400, and the reduction treatment apparatus 500, which are configured as described above, operate as described above under the control of the controller 800. Thus, the substrate processing method of the embodiment may be implemented.

### Experimental Example

In Experimental Example, as the Ru film formed by the non-electrolytic plating, Sample 1 in the as-depo state, Sample 2 subjected to only the reduction annealing after the plating, and Samples 3 and 4 sequentially subjected to the Ar plasma treatment and the reduction annealing after the plating, were prepared. In the reduction annealing, the foaming gas (4% of H₂) was used as the reducing gas, and the reduction annealing was performed at 400 degrees C. for 10 minutes. In addition, Samples 3 and 4 have been subjected to the Ar plasma treatment while changing the pressure and temperature under a common condition in which the Ar gas of 100% is used, the radio-frequency power (HF) applied to the upper electrode is 1,500 W, the radio-frequency power (LF) applied to the lower electrode is 500 W, and the time period is 100 seconds. That is, in Sample 3, the pressure was set to 300 mTorr and the temperature was set to 80 degrees C. In Sample 4, the pressure was set to 200 mTorr and the temperature was set to 120 degrees C.

As results of SEM observation, Sample 1 in the as-depo state has not sufficiently undergone the crystal growth and came into a state close to the amorphous state. In Sample 2 subjected to only the reduction annealing, the crystal growth was observed, but a plurality of cracks were observed. In Sample 3 among Samples subjected to the Ar plasma treatment, almost no crack was formed in, but some defects were found in the film. In Sample 4 among Samples subjected to the Ar plasma treatment, almost no crack and defect have found in the film.

As a result of measuring the resistivity of the film, the resistivity of Sample 1 in the as-depo state was 113 μΩ·cm and the resistivity of Sample 2 subjected to only the reduction annealing was 43.7 μΩ. Meanwhile, the resistivity of Samples 3 and 4 subjected to the Ar plasma treatment were at a low level of 15.1 μΩ cm.

From the above results, it was found that, by sequentially performing the Ar plasma treatment and the reduction treatment on the Ru film formed by the non-electrolytic plating, it is possible to stably the low-resistance Ru film.

### Other Applications

In the above, the embodiments have been described, but it should be understood that the embodiments disclosed herein are illustrative in all respects and are not restrictive. The embodiments described above may be omitted, replaced, and changed in various ways without departing from the accompanying claims and the subject thereof.

For example, the non-electrolytic plating apparatus of the above embodiment is merely an example, and other apparatuses having various configurations may be used. In addition, in the above embodiment, the inert-gas plasma treatment apparatus is merely an example, and other apparatuses having various configurations may be used. As described above, the plasma is not limited to the capacitively-coupled plasma, and other plasmas such as the inductively-coupled plasma and the microwave plasma may be used.

In addition, in the above embodiment, the case in which a semiconductor substrate (semiconductor wafer) having a semiconductor base substance is used as the substrate has been illustrated. However, the substrate is not limited to the semiconductor wafer, and may be another substrate such as a flat panel display (FPD) substrate, a ceramic substrate or the like. In addition, in the above embodiment, the case in which the Ru film is embedded in the fine via has been illustrated, but the present disclosure is not limited thereto.

According to the present disclosure, it is possible to provide a substrate processing method and a substrate processing system which case in which capable of stably forming a low-resistance Ru film using a non-electrolytic plating.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method comprising:
forming a Ru film on a substrate by a non-electrolytic plating;
performing a treatment using plasma of an inert gas on the substrate on which the Ru film is formed; and
performing a reduction treatment on the substrate after the treatment using the plasma of the inert gas.

2. The substrate processing method of claim 1, wherein the forming Ru film by the non-electrolytic plating further comprises applying a non-electrolytic plating liquid onto the substrate, precipitating a plating film which becomes Ru film by heating the substrate, and drying the substrate.

3. The substrate processing method of claim 2, wherein the substrate when precipitating the plating film is heated at 50 degrees C. to 85 degrees C.

4. The substrate processing method of claim 1, wherein, in the treatment using the plasma of the inert gas, the inert gas includes an Ar gas or a N₂ gas.

5. The substrate processing method of claim 4, wherein the treatment using the plasma of the inert gas is performed in a state in which a bias is applied to the substrate.

6. The substrate processing method of claim 1, wherein the substrate includes an underlying wiring, an insulating film formed on the underlying wiring, and a via provided in the insulating film such that the underlying wiring is exposed from a bottom of the via, and wherein Ru film grows from the underlying wiring in a bottom-up manner, using the underlying wiring as a catalyst.

7. The substrate processing method of claim 1, wherein the performing the reduction treatment on the substrate is performed by a reduction annealing in which the substrate is heated at an atmospheric pressure while supplying a reducing gas.

8. The substrate processing method of claim 7, wherein the reducing gas is at least one selected from a group consisting of a foaming gas, a H₂ gas, and a formic acid.

9. The substrate processing method of claim 7, wherein a heating temperature of the substrate when the reduction treatment is performed on the substrate is in a range of 200 degrees C. to 430 degrees C.

10. The substrate processing method of claim 1, wherein the performing the reduction treatment on the substrate is performed by a hydrogen-plasma treatment in which the substrate is treated using plasma of a gas including a H₂ gas.

11. The substrate processing method of claim 1, wherein the treatment using the plasma of the inert gas is performed at a pressure in a range of 13.3 Pa to 266.6 Pa.

12. The substrate processing method of claim 1, wherein the treatment using the plasma of the inert gas is performed at a temperature in a range of 70 degrees C. to 400 degrees C.

13. The substrate processing method of claim 1, wherein a time period required for the treatment using the plasma of the inert gas is 5 seconds to 300 sec.

14. A substrate processing system comprising:
a non-electrolytic plating apparatus configured to form a Ru film on a substrate by a non-electrolytic plating;
an inert-gas plasma treatment apparatus configured to perform a treatment using plasma of an inert gas on the substrate on which the Ru film is formed by the non-electrolytic plating apparatus; and
a reduction treatment apparatus configured to perform a reduction treatment on the substrate which has been subjected to the treatment by the inert-gas plasma treatment apparatus.

15. The substrate processing system of claim 14, wherein, in the inert-gas plasma treatment apparatus, the inert gas includes an Ar gas or a N₂ gas.

16. The substrate processing system of claim 15, wherein the inert-gas plasma treatment apparatus includes a bias applying apparatus configured to apply a bias to the substrate.

17. The substrate processing system of claim 14, wherein the reduction treatment apparatus is a reduction annealing apparatus configured to heat the substrate at an atmospheric pressure while supplying a reducing gas.

18. The substrate processing system of claim 14, wherein the reduction treatment apparatus is a hydrogen-plasma treatment apparatus configured to perform a treatment using a plasma of a gas including a H₂ gas on the substrate.
